(19) United States
(12) Patent Application Publication
(10) Pub. No.: US 2019/0252094 A1
(43) Pub. Date: Aug. 15, 2019

(54) Electrical Connection Unit and Battery System

(71) Applicant: TE Connectivity Germany GmbH, Bensheim (DE)

(72) Inventors: Ronald Wienziers, Dieburg (DE); Patrick Wrobel, Einhausen (DE); Holger Hinrichs, Viernheim (DE); Gregor Gassmann, Griesheim (DE); Joachim Hoffmann, Lorsch (DE)

(73) Assignee: TE Connectivity Germany GmbH, Bensheim (DE)

(21) Appl. No.: 16/272,387

(22) Filed: Feb. 11, 2019

(30) Foreign Application Priority Data
Feb. 12, 2018 (DE) 102018202128.7

(51) Int. Cl. H01B 7/42; H01R 13/00; H01R 13/533; B60L 53/16; B60L 53/18; B60L 53/302; H05K 7/20

(52) U.S. Cl. CPC H01B 7/423; H01R 13/005; H01R 13/533; H01R 2201/26; B60L 53/18; B60L 53/302; H05K 7/2039; B60L 53/16

(57) ABSTRACT

An electrical connection unit comprising a first electrical terminal, a first fluidic terminal for attaching a coolant source, and a second electrical terminal connected to an electrically conductive cable and electrically connected to the first electrical terminal. The second electrical terminal is formed as a second fluidic terminal fluidly connecting a cooling channel of the cable through which a coolant can flow to the first fluidic terminal.

### CROSS-REFERENCE TO RELATED APPLICATION

This application claims the benefit of the filing date under 35 U.S.C. § 119(a)-(d) of German Patent Application No. 102018202128.7, filed on Feb. 12, 2018.

### FIELD OF THE INVENTION

The present invention relates to an electrical connection unit and, more particularly, to an electrical connection unit with integrated cooling.

### BACKGROUND

All electronic components, appliances and circuits generate excess heat, and thus require thermal management in order to improve reliability and prevent premature failure. In the electrical connection of a battery system in a motor vehicle, high currents and thus considerable amounts of heat arise at the electrical contacts of the battery and must be dissipated as quickly and efficiently as possible to avoid dangerous overheating.

There are various techniques for cooling electrical assemblies, for example, air cooling using fans or thermoelectric cooling, which is based on the Peltier effect. Conventional air cooling systems with fans are limited in their capacity to dissipate heat and are therefore suitable only to a limited extent for use with battery systems. It is substantially more efficient to discharge heat via a fluid, for example a cooling liquid such as water or an oil.

A device for cooling a plug connection is known from DE 102015221571 A1, and comprises a charging plug, a contact bushing receiving the charging plug, a first electrical line connected to the contact bushing, and a second electrical line connected to the charging plug. The first electrical line has a first cavity and/or the second electrical line has a second cavity along the electrical line, via which a coolant is conducted. A tube, for example, which surrounds the charging cable, has a coolant flow through it. This coolant can be air, oil, water or another fluid suitable for dissipating heat.

Application DE 1160053 B discloses cooling electrically conductive high frequency (HF) cables with a coolant liquid guided in the cable. A copper hollow tube is arranged in the cable in a tube composed of rubber, such that the copper hollow tube serves to conduct current and the rubber tube serves to conduct the coolant further, the coolant simultaneously washing around the wires of the current conductor.

Ring support couplers for coupling fluids are known, for example, from EP 0646748 B1 and are used if fluid lines, which can lie in any desired angular positions in relation to each other, have to be connected to each other. EP 0646748 discloses a screw as a hollow cylinder, which is closed at the head end of the screw and open at the thread end. At the head end, the screw has two holes lying opposite each other. A ring terminal is composed of a ring which has a hole on one side, onto which a terminal support is placed, in such a way that the support points outwards in the radial direction. The ring terminal is plugged onto the hollow screw between two sealing rings. In this configuration, a liquid can be conducted around an angle.

These known arrangements, however, offers no practicable solution for cooling at the contact point to a battery.

### SUMMARY

An electrical connection unit comprising a first electrical terminal, a first fluidic terminal for attaching a coolant source, and a second electrical terminal connected to an electrically conductive cable and electrically connected to the first electrical terminal. The second electrical terminal is formed as a second fluidic terminal fluidly connecting a cooling channel of the cable through which a coolant can flow to the first fluidic terminal.

### BRIEF DESCRIPTION OF THE DRAWINGS

The invention will now be described by way of example with reference to the accompanying Figures, of which:

FIG. 1 is a sectional perspective view of an electrical connection unit according to an embodiment;

FIG. 2 is a sectional side view of the electrical connection unit;

FIG. 3 is an side view of the electrical connection unit;

FIG. 4 is another side view of the electrical connection unit;

FIG. 5 is a perspective view of the electrical connection unit; and

FIG. 6 is a plan view of the electrical connection unit.

### DETAILED DESCRIPTION OF THE EMBODIMENT(S)

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will fully convey the concept of the disclosure to those skilled in the art.

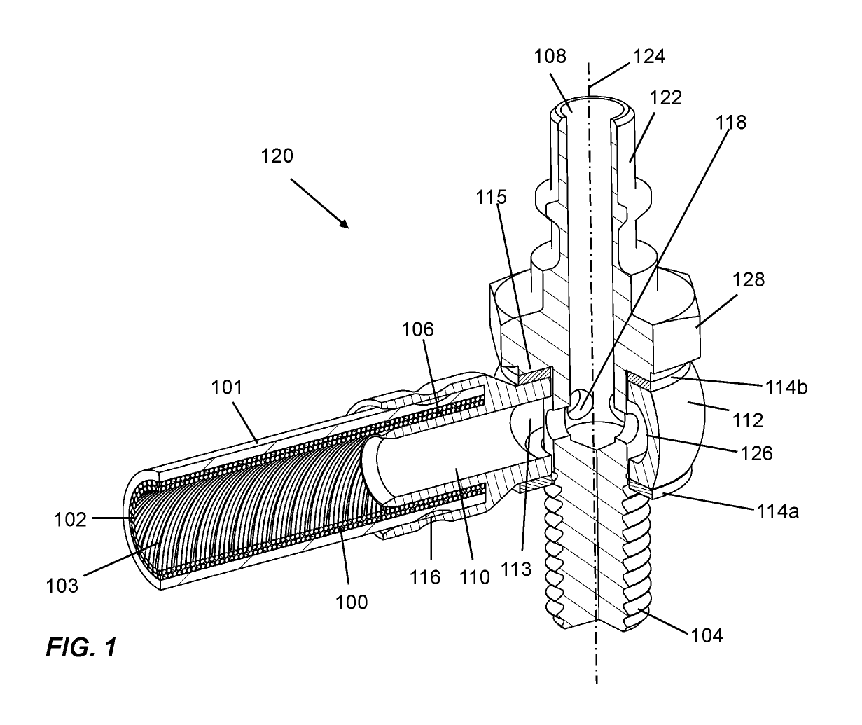

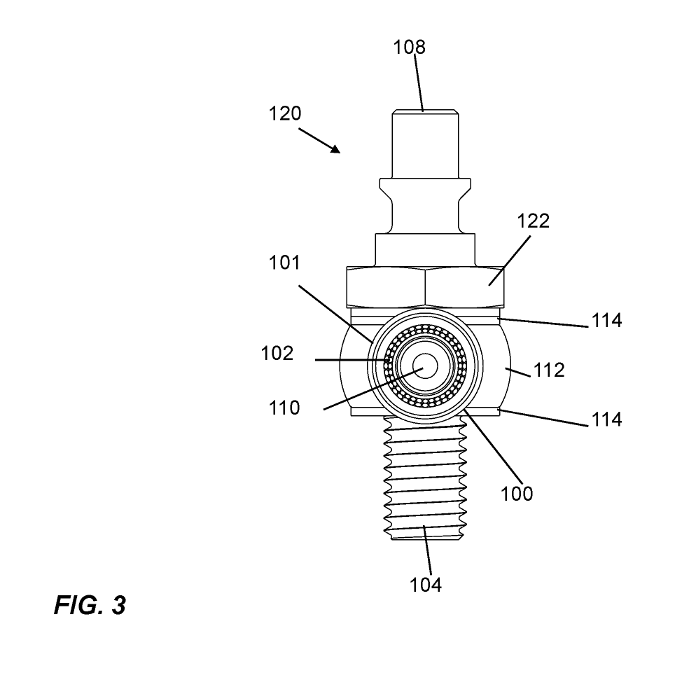

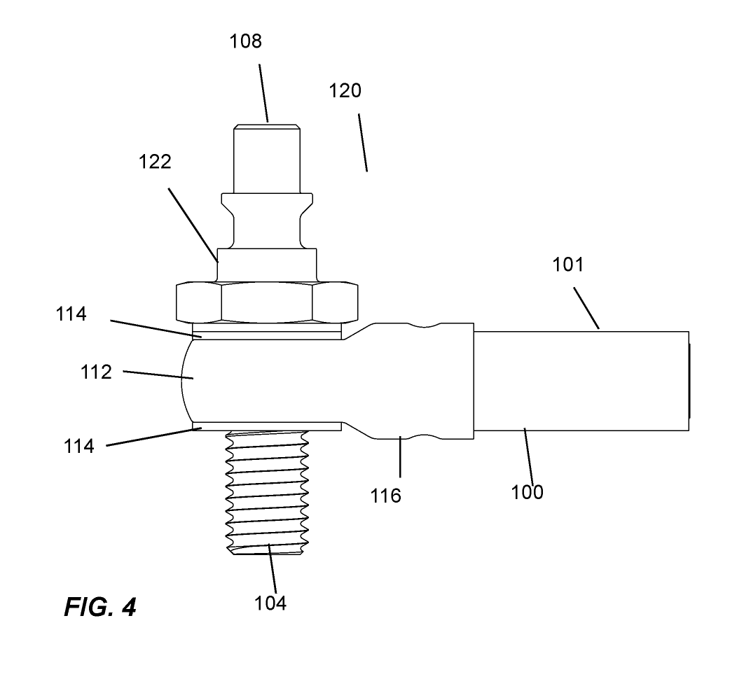

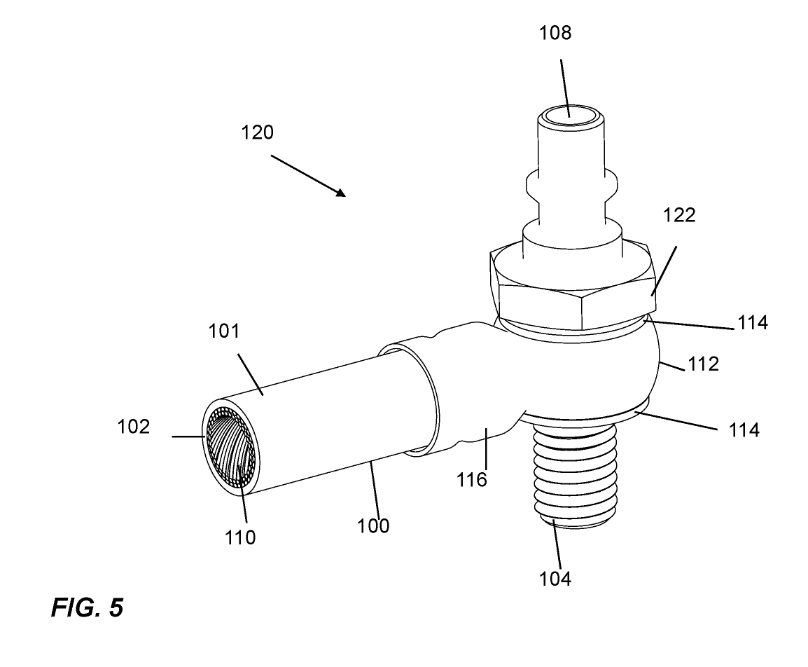

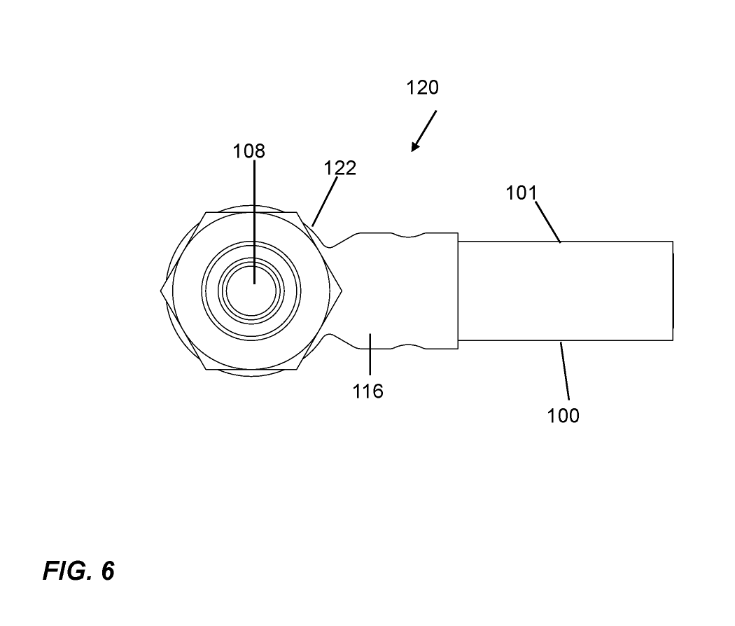

An electrical connection unit 120 according to an embodiment is shown in FIGS. 1-6. The electrical connection unit 120 is adapted to electrically contact a battery contact, and has a first electrical terminal 104 formed as a screw connection in the shown embodiment. The first electrical terminal 104 may have other configurations in other embodiments, such as a plug connector or a press-in connection, for example.

The first electrical terminal 104, as shown in FIGS. 1-5, is part of a base body 122, which extends along a first longitudinal axis 124. The base body 122 is partly hollow and has a first fluidic terminal 108 for attaching a coolant line. In the embodiment shown, the first fluidic terminal 108 is configured as a rapid coupler. In this way, the electrical connection unit 120 can be attached quickly and releasably, for example, to the vehicle-internal cooling circuit of a battery. The first longitudinal axis 124 extends along a plugging direction of the first fluidic terminal 108.

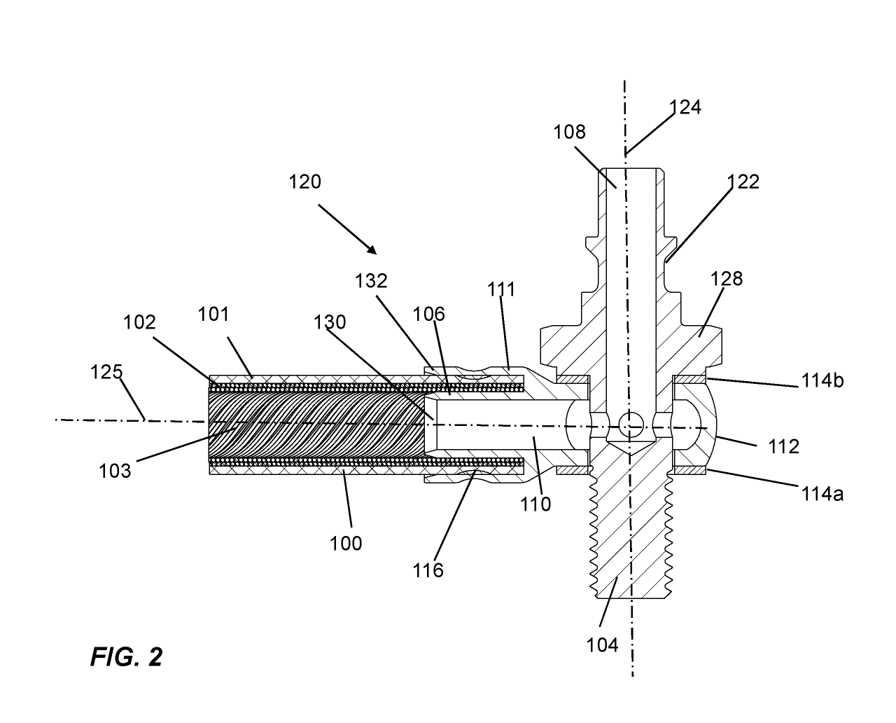

The electrical connection unit 120 has a second electrical terminal 106 connected to a cable 100, as shown in FIGS. 1 and 2, and providing both electrical contacting to a conductor 102 of the cable 100, electrically connecting the cable 100 to the battery, as well as fluidic contacting. The cable 100 has an electrically insulating sheath 101, in the interior of which the conductor 102 is arranged. The cable 100 forms a cooling channel 103 in its interior, through which coolant can flow. In an embodiment, the sheath 101 is a Teflon tube and the conductor 102 is a metal mesh 102. In order to achieve optimum conductivity, copper is used as the metal of the metal mesh 102. The conductivity of this construction can be increased by using several layers of the copper mesh 102. In order to cool this conductor 102, a coolant is conducted through the cavity formed by the copper mesh 102. By way of the structure of the mesh 102, a very large interface can be achieved between the copper and the coolant, as a result of which efficient cooling is made possible. The coolant is electrically non-conductive in an embodiment; insulation from the conductor 102 can be dispensed with, as a result of which, the transition of heat is not impaired by an additional insulator and the manufacture of the cable 100 is simplified.

The second electrical terminal 106 is formed as a second fluidic terminal 110. The second fluidic terminal 110 is arranged on a ring coupler 112, as shown in FIGS. 1-3 and 5, so that the terminal 110 can rotate around the axis 124. This arrangement facilitates mounting of the electrical connection unit 120. In another embodiment, the combined second electrical and fluidic terminal 106, 110 can also be formed integrally on the base body 122.

The base body 122 has openings 118, as shown in FIG. 1, arranged equidistantly around its circumference in order to allow coolant to flow into a coolant chamber 113 formed by the ring coupler 112. The coolant flow is directed in such a way that it runs from the first fluidic terminal 108 through the openings 118 to the second fluidic terminal 110, and enters into the electrically conductive cooling channel 103 of the cable 100. The flow may have a different direction in other embodiments. The arrangement makes it possible for both the cable 100 and also the immediate environment of the conductors 104, 106 through which current flows to be able to be cooled by the coolant. As a result, heat produced can be discharged significantly better than in the case of known arrangements, and dangerous overheating can be avoided.

As interface 115 between the base body 122 and the ring coupler 112, as shown in FIG. 1, is sealed by an electrically conducive sealing device 114. In embodiment, the electrically conductive sealing device 114 is two copper rings 114 including a first copper ring 114a disposed below the ring coupler 112 along the longitudinal axis 124 and a second copper ring 114b disposed on top of the ring coupler 112 along the longitudinal axis 124.

In the non-mounted state on a mating contact carrier, a support 111 of the ring coupler 112, which forms the second electrical terminal 106 and the second fluidic terminal 110, can still rotate around the longitudinal axis 124 and the rings 114 have no sealing function. As soon as the screw connection of the first electrical terminal 104, however, is mounted with sufficient firmness on the mating contact carrier, the first copper seal 114a lies on a counter bearing of the mating contact carrier. By way of the forces acting in the axial direction along the longitudinal axis 124, the copper seals 114 are pressed against the ring coupler 112. The ring coupler 112 can no longer rotate around the longitudinal axis 124 and the interface 115 with the base body 122 is sealed in a liquid-tight manner.

In order to facilitate the mounting of the electrical connection unit 120, an actuation unit 128 similar to a screw nut is arranged on the base body 122 as shown in FIGS. 1-5. The electrical connection unit 120 can be mounted using conventional mounting tools, for example on a battery. If the first fluidic terminal 108 is still open, the actuation unit 128 is easily accessible for a tool and the base body 122 can be screwed securely, without a support 111 shown in FIG. 2 which forms the second electrical and fluidic terminal 106, 110, rotating with the actuation unit 128. Only shortly before the final mounting position is reached does the ring coupler 112 become jammed and no longer able to be rotated. The cable 100 can thus already be mounted on the second electrical terminal 106 in the factory.

The support 111, as shown in FIG. 2, has an inner sleeve 130 and an outer sleeve 132. In a radial direction, a circumferential gap is formed between the inner sleeve 130 and the outer sleeve 132, into which gap the cable 100 is inserted. In a crimp region 116, the outer sleeve 132 is pressed radially inwards in the direction of the cable 100 and the inner sleeve 130. As a result, the conductor 102 of the cable 100 is pressed onto the outside of the inner sleeve 130, such that an electrical contacting takes place. Moreover, the crimp region 116 also forms a radially circumferential press-fit connection between the outer sleeve 132 and the electrically insulating sheath 101 of the cable 100. The mechanical fixing of the cable 100 and a fluidic seal between the support 111 and the fluid channel 103 are thus established.

As shown in FIGS. 1 and 2, the coolant chamber 113 has a rounded inner surface 126 which extends torically around an outer wall of the base body 122 and makes it possible to conduct cooling liquid, which flows through the openings 118, in an annular manner around the base body 122 into the second fluidic terminal 110. A longitudinal axis 125 of the support 111 extends perpendicular to the first longitudinal axis 124, to form a space-saving yet flexible electrical connection unit 102.

In an embodiment, the electrical connection unit 120 is used in a battery system of a motor vehicle. The battery system has an electrical contact connected to the first electrical terminal 104 and the first fluidic terminal 108 is attached to a coolant reservoir of the battery system.

What is claimed is:

1. An electrical connection unit, comprising:
a first electrical terminal;
a first fluidic terminal for attaching a coolant source; and
a second electrical terminal connected to an electrically conductive cable and electrically connected to the first electrical terminal, the second electrical terminal is formed as a second fluidic terminal fluidly connecting a cooling channel of the cable through which a coolant can flow to the first fluidic terminal.

2. The electrical connection unit of claim 1, wherein the cable includes a conductor surrounded by an electrically insulating sheath and forming the cooling channel in an interior of the conductor.

3. The electrical connection unit of claim 1, wherein the second electrical terminal is arranged at a ring coupler.

4. The electrical connection unit of claim 3, wherein the ring coupler holds the second terminal rotatably around a longitudinal axis of the first electrical terminal.

5. The electrical connection unit of claim 4, further comprising a base body including the first electrical terminal, the first electrical terminal having a first longitudinal axis extending along a plugging direction of the first fluidic terminal.

6. The electrical connection unit of claim 5, wherein the second electrical terminal has a second longitudinal axis that is not parallel to the plugging direction.

7. The electrical connection unit of claim 6, wherein the ring coupler forms a coolant chamber within the base body.

8. The electrical connection unit of claim 7, wherein the first fluidic terminal is fluidly connected to the coolant chamber via an opening in the base body.

9. The electrical connection unit of claim 8, wherein a plurality of openings are arranged equidistantly around a circumference of the base body.

10. The electrical connection unit of claim 5, further comprising an electrically conductive sealing device sealing an interface between the base body and the ring coupler.

11. The electrical connection unit of claim 10, wherein the electrically conductive sealing device includes a copper ring.

12. The electrical connection unit of claim 1, wherein the cable is connected to the second electrical terminal by a crimp connection.

13. The electrical connection unit of claim 12, wherein the cable has an electrically insulating sheath fluidly sealing the cable at the crimp connection.

14. The electrical connection unit of claim 1, wherein the first electrical terminal is a screw connection.

15. A battery system, comprising:
an electrical contact; and
an electrical connection unit including a first electrical terminal connected to the electrical contact, a first fluidic terminal attached to a coolant reservoir, and a second electrical terminal connected to an electrically conductive cable and electrically connected to the first electrical terminal, the second electrical terminal is formed as a second fluidic terminal fluidly connecting a cooling channel of the cable through which a coolant can flow to the first fluidic terminal.

16. The battery system of claim 15, wherein the second electrical terminal is arranged at a ring coupler.

17. The battery system of claim 16, wherein the ring coupler is mechanically fixed by a connection between the electrical contact and the first electrical terminal.
